(19) United States
(12) Patent Application Publication
(10) Pub. No.: US 2026/0101489 A1
(43) Pub. Date: Apr. 9, 2026

(54) CFET SRAM DEVICE, LAYOUT, AND METHOD

(71) Applicant: TAIWAN SEMICONDUCTOR MANUFACTURING COMPANY, LTD., Hsinchu (TW)

(72) Inventors: Ping-Wei WANG, Hsinchu (TW); Jui-Lin CHEN, Hsinchu (TW)

(21) Appl. No.: 19/058,371

(22) Filed: Feb. 20, 2025

Related U.S. Application Data
(60) Provisional application No. 63/704,278, filed on Oct. 7, 2024.

(51) Int. Cl. H10B 10/00; G11C 5/06; G11C 11/412; H10D 89/10

(52) U.S. Cl. CPC H10B 10/12; G11C 5/063; G11C 11/412; H10B 10/18; H10D 89/10

(57) ABSTRACT

An IC device includes CFETs configured as a SRAM, a first CFET includes first pull-down and pull-up transistors at first and second elevations along a first direction, second and third CFETs includes pass gates at the first elevation and aligned with the first pull-down transistor in second and third directions perpendicular to the first direction, and a fourth CFET includes second pull-down and pull-up transistors at the first and second elevations and aligned with the pass gates in the second and third directions. First and second bit lines extend in the third direction at a third elevation and are electrically connected to S/D structures of the pass gates, and a reference voltage line extends between the bit lines at the third elevation and is electrically connected to a S/D structure of a pull-down transistor.

### PRIORITY CLAIM

The present application claims the priority of U.S. Provisional Application No. 63/704,278, filed Oct. 7, 2024, which is incorporated herein by reference in its entirety.

### BACKGROUND

The ongoing trend in miniaturizing integrated circuits (ICs) has resulted in progressively smaller devices which consume less power, yet provide more functionality at higher speeds than earlier technologies. Such miniaturization has been achieved through design and manufacturing innovations tied to increasingly strict specifications. Various electronic design automation (EDA) tools are used to generate, revise, and verify designs for semiconductor devices while ensuring that IC structure design and manufacturing specifications are met.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1D are a schematic diagram, plan view, and cross-sectional views of an IC device and layout diagram, in accordance with some embodiments.

FIGS. 2A-2D are plan and cross-sectional views of an IC device and layout diagram, in accordance with some embodiments.

FIG. 3 is a plan view of an IC device and layout diagram, in accordance with some embodiments.

FIG. 4 is a plan view of an IC device and layout diagram, in accordance with some embodiments

FIG. 5 is a flowchart of a method of manufacturing an IC device, in accordance with some embodiments.

FIG. 6 is a flowchart of a method of generating an IC layout diagram, in accordance with some embodiments.

FIG. 7 is a block diagram of an IC layout diagram generation system, in accordance with some embodiments.

FIG. 8 is a block diagram of an IC manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In various embodiments, an integrated circuit (IC) device, layout diagram, and manufacturing method are directed to stacked complementary field-effect transistors (CFETs) positioned at first and second elevations along a first direction and arranged as a static random-access memory (SRAM) device, first and second bit lines extending in a second direction at a third elevation and electrically connected to source/drain (S/D) structures of pass-gate transistors of the SRAM device at the first elevation, and a reference voltage line extending in the second direction between the first and second bit lines at the third elevation and electrically connected to a S/D structure of a pull-down transistor of the SRAM device at the first elevation.

By including the reference voltage line between the first and second bit lines, the IC device is capable of having reduced capacitive coupling between the first and second bit lines of the SRAM device compared to approaches that do not include a reference voltage line between bit lines of an SRAM device, thereby enabling relatively higher operating speeds.

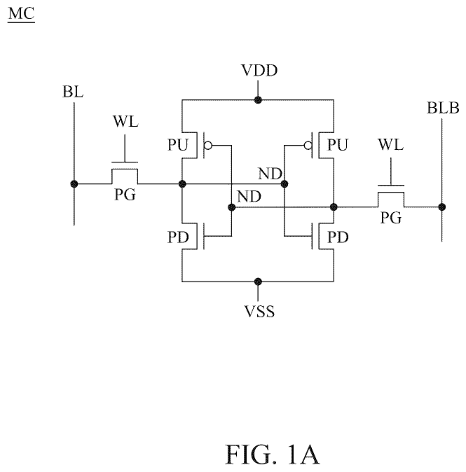

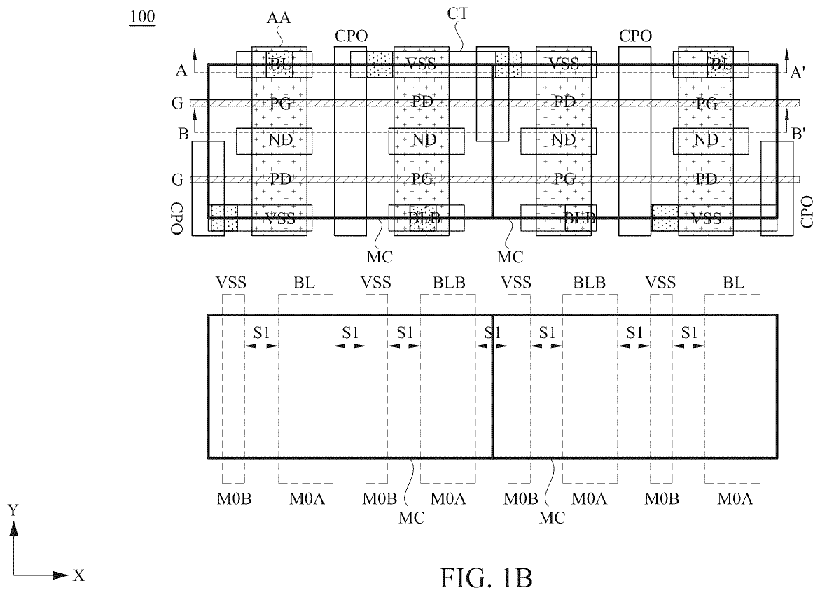

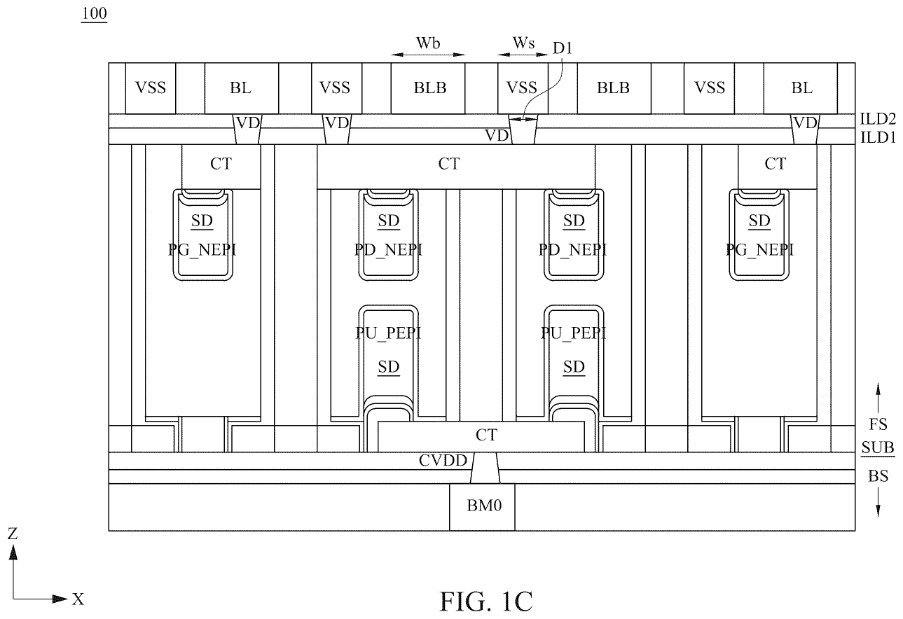

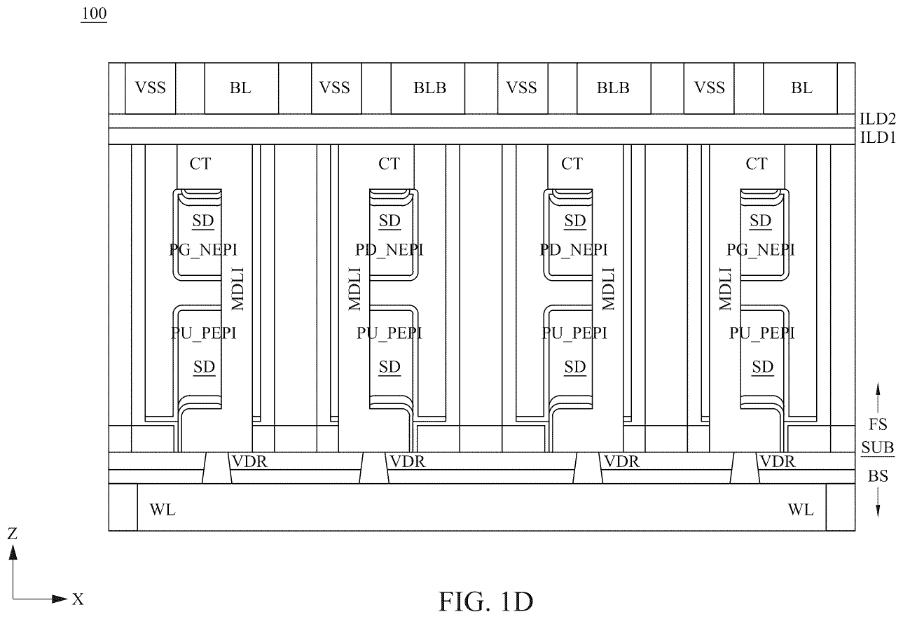

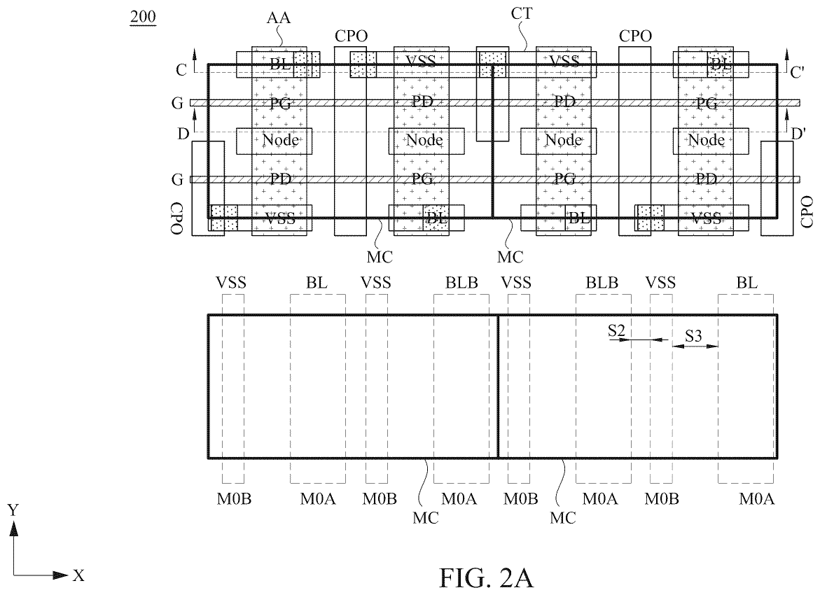

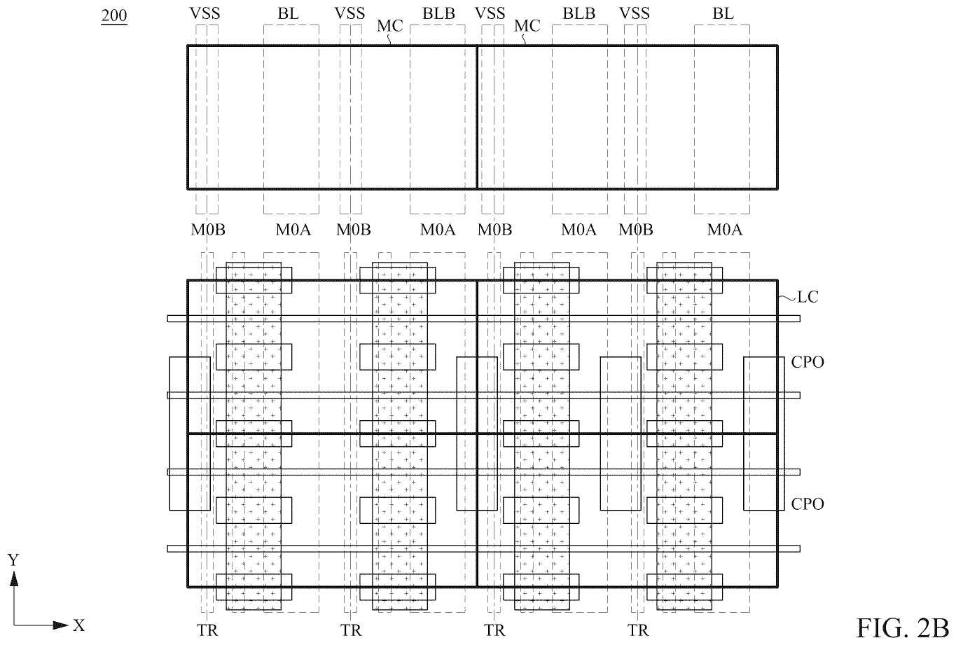

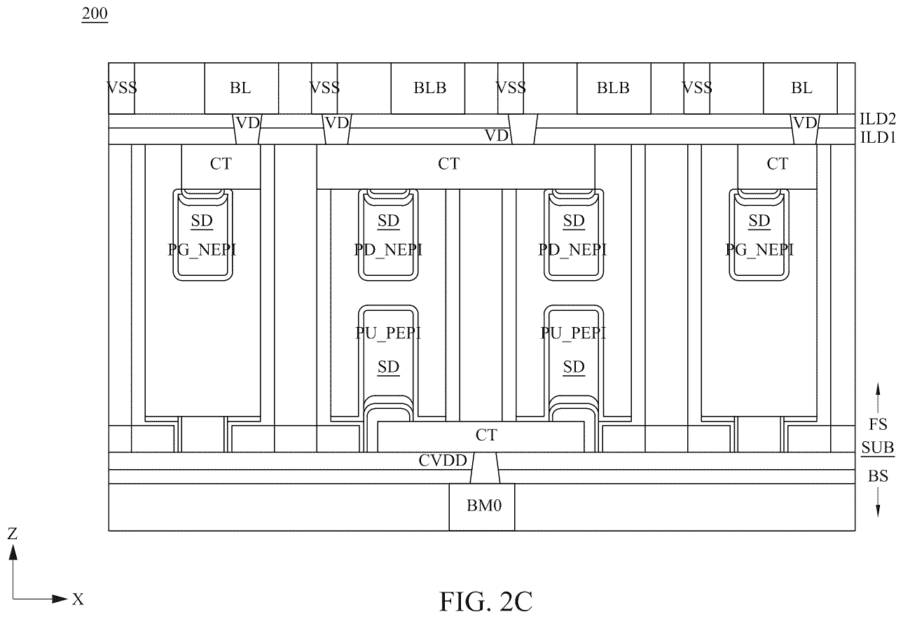

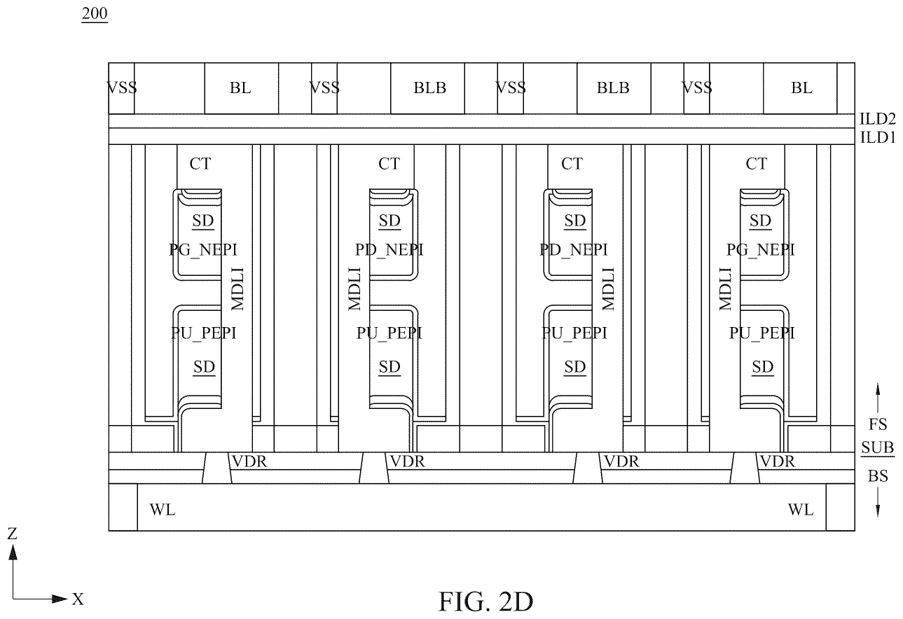

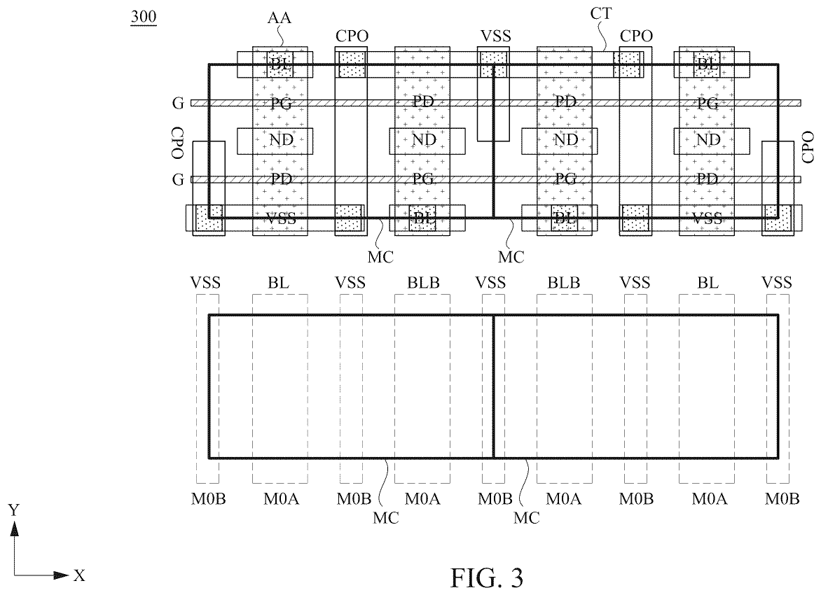

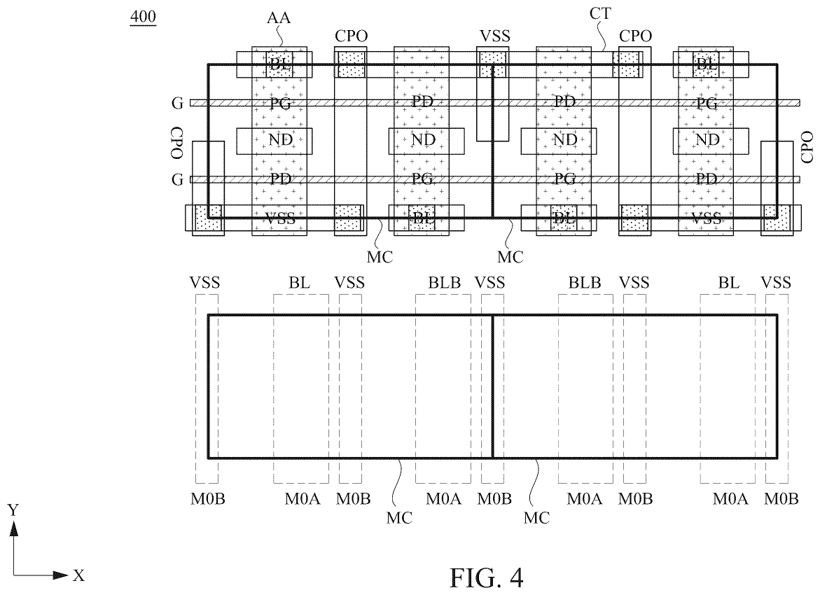

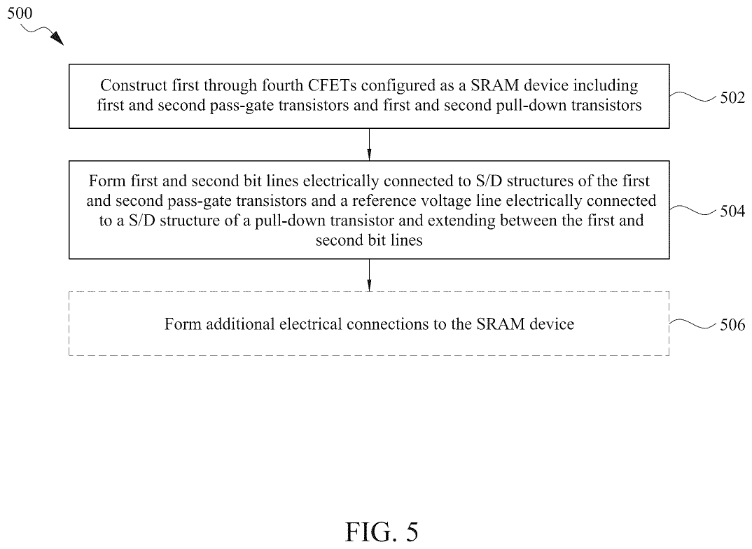

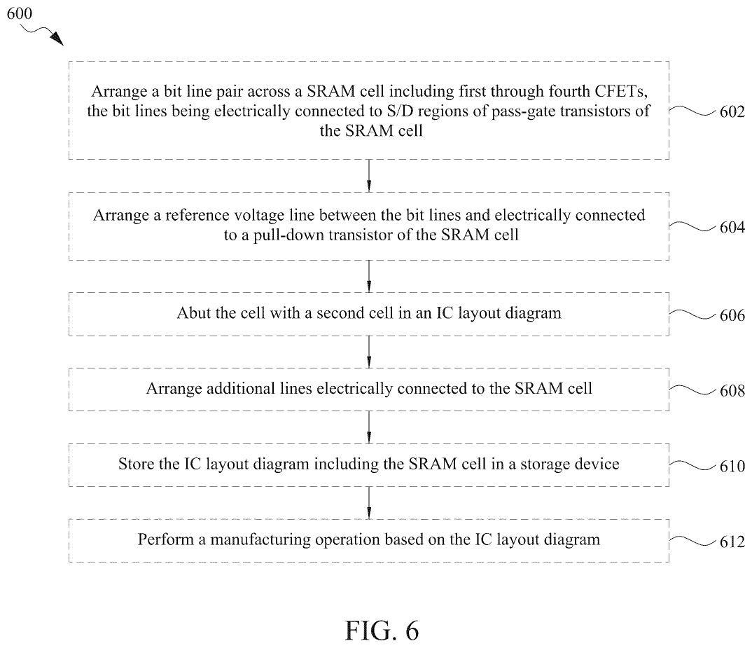

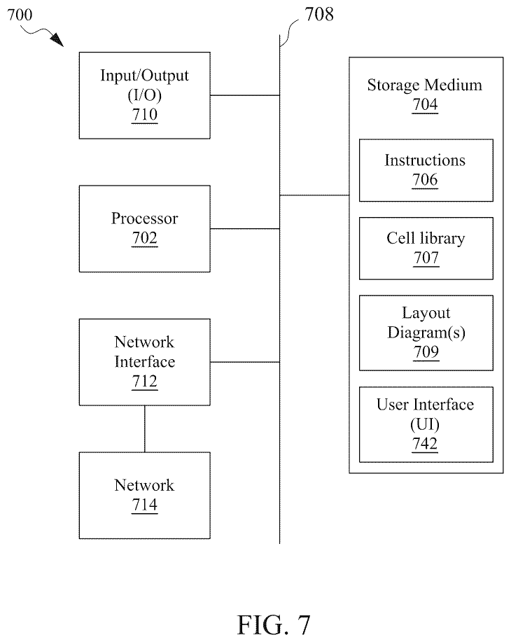

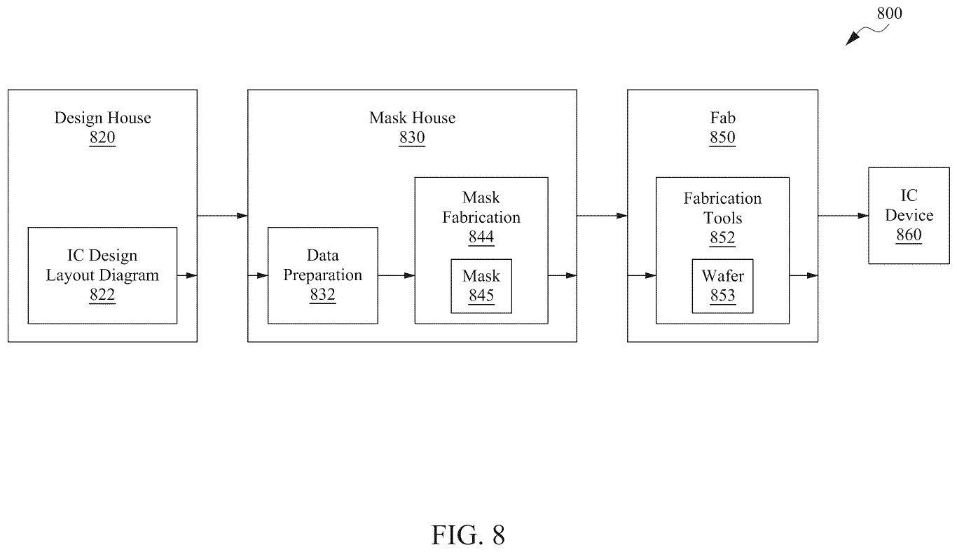

As discussed below, in accordance with various embodiments, FIGS. 1A-1D are a schematic diagram and plan and cross-sectional views of an IC device and layout diagram 100, FIGS. 2A-2D are plan and cross-sectional views of an IC device and layout diagram 200, FIGS. 3 and 4 are plan views of respective IC devices and layout diagrams 300 and 400, FIG. 5 is a flowchart of a method 500 of manufacturing an IC, and FIG. 6 is a flowchart of a method 600 of generating an IC layout diagram, e.g., using an IC layout diagram generation system 700 depicted in FIG. 7 and/or in accordance with an IC manufacturing flow 800 depicted in FIG. 8.

Each of the figures herein, e.g., FIGS. 1A-4, is simplified for the purpose of illustration. The figures are views of IC structures, devices, and layout diagrams with various features included and excluded to facilitate the discussion below. In various embodiments, an IC structure, device and/or layout diagram includes one or more features corresponding to power distribution structures, metal interconnects, contacts, vias, gate structures, source/drain (S/D) structures, active areas, bulk connections, or other transistor elements, isolation structures, or the like, in addition to the features depicted in FIGS. 1A-4.

In each of IC layout diagrams/devices 100-400, reference designators represent both IC device features and the IC layout features used to at least partially define the corresponding IC device features in a manufacturing process, e.g., method 500 discussed below with respect to FIG. 5 and/or the IC manufacturing flow associated with IC manufacturing system 800 discussed below with respect to FIG. 8. Accordingly, each of IC layout diagrams/devices 100-400 represents a view of both an IC layout diagram 100-400 and a corresponding IC device 100-400.

Each of IC layout diagrams/devices 100-400 discussed below includes arrangements of some or all of at least one of a substrate, an active region/area, a S/D region/structure, a contact and/or interconnect region/structure, a gate region/structure, a metal region/segment, a via region/structure, and/or a dielectric region/layer, each discussed below.

A substrate, e.g., a substrate SUB, is a portion, e.g., a die, or all of a semiconductor or other wafer, e.g., a silicon (Si) wafer, or an epitaxial Si layer, suitable for forming one or more IC devices, e.g., IC devices 100-400. In each of the embodiments discussed below, a substrate, e.g., a semiconductor substrate, includes a front side, e.g., a front side FS, within which a first subset of the features of the IC devices are formed through a first set of manufacturing processes, e.g., front-end-of-line (FEOL) processes, middle-end-of-line (MEOL) processes, and back-end-of-line (BEOL) processes, and a back side, e.g., a back side BS, within which a second subset of the features of the IC devices are formed through a second set of manufacturing processes, e.g., backside metallization processes, performed after the first set of manufacturing processes are performed.

An active region/area, e.g., an active region/area AA, is a region in an IC layout diagram included in a manufacturing process as part of defining an active area, also referred to as an oxide diffusion or definition (OD) in some embodiments, in the substrate, either directly or in an n-well or p-well region/area, in which one or more IC device features, e.g., a S/D structure, is formed. In some embodiments, an active area is an n-type or p-type active area of a stacked complementary field-effect transistor (CFET) or another transistor configuration including a gate region/structure.

In various embodiments, an active area (structure) includes one or more of a semiconductor material, e.g., silicon (Si), silicon-germanium (SiGe), silicon-carbide (SiC), or the like, a dopant material, e.g., boron (B), aluminum (Al), phosphorous (P), arsenic (As), gallium (Ga), or another suitable material.

In some embodiments, an active region is a region in an IC layout diagram included in the manufacturing process as part of defining a nano-sheet structure, e.g., a continuous volume of one or more layers of one or more semiconductor materials having either n-type or p-type doping. In various embodiments, individual nano-sheet layers include a single monolayer or multiple monolayers of a given semiconductor material.

A S/D region/structure, e.g., an S/D region/structure SD, is a region in the IC layout diagram included in the manufacturing process as part of defining a S/D structure, also referred to as a semiconductor structure in some embodiments, configured to have a doping type opposite that of the corresponding active region/area. In some embodiments, a S/D region/structure is configured to have lower resistivity than an adjacent channel feature, e.g., a portion of the corresponding active region/area of a CFET or other transistor. In some embodiments, a S/D region/structure includes one or more portions having doping concentrations greater than one or more doping concentrations present in the corresponding channel feature. In some embodiments, a S/D region/structure includes one or more epitaxial regions of a semiconductor material, e.g., Si, SiGe, and/or silicon-carbide SiC. A S/D region/structure, also referred to as a S/D terminal in some embodiments, may refer to a source or a drain, individually or collectively, dependent upon the context.

A contact or interconnect region/structure, e.g., a contact region/structure CT or an interconnect region/structure MDLI, is a conductive region in the IC layout diagram included in the manufacturing process as part of defining a contact or interconnect structure, also referred to as a conductive segment or metal-like defined (MD) conductive line, trace, or structure, in and/or on the substrate. In some embodiments, a contact or interconnect region overlaps an active area at a location of one or more S/D regions in the IC layout diagram, and the corresponding contact or interconnect structure contacts and is electrically connected to the one or more S/D structures of the active area.

In some embodiments, a contact or interconnect structure includes a portion of at least one metal layer, e.g., a contact layer, overlying and contacting the substrate and having a thickness sufficiently small to enable formation of an insulation layer between the contact or interconnect structure and an overlying metal layer, e.g., the first metal layer. In various embodiments, an MD segment includes one or more of copper (Cu), silver (Ag), tungsten (W), titanium (Ti), nickel (Ni), tin (Sn), aluminum (Al) or another metal or material suitable for providing a low resistance electrical connection between IC structure elements, i.e., a resistance level below a predetermined threshold corresponding to one or more tolerance levels of a resistance-based effect on circuit performance.

In various embodiments, a contact or interconnect structure includes a section of a substrate and/or an epitaxial layer having a doping level, e.g., based on an implantation process, sufficient to cause the structure to have the low resistance level. In various embodiments, a doped contact or interconnect structure includes one or more dopant materials having doping concentrations of about 1*1016 per cubic centimeter (cm-3) or greater.

In some embodiments, a manufacturing process includes two or more contact or interconnect structure layers, and a contact or interconnect region/structure, e.g., contact region/structure CT or interconnect region/structure MDLI, refers to one or more of the two or more contact or interconnect structure layers in the manufacturing process. In some embodiments, a contact or interconnect structure is configured to be electrically connected to the S/D structure of a single one of a p-type or n-type FET of a CFET, and to be electrically isolated from the S/D structure of the other of the p-type or n-type FET of the CFET. In some embodiments, a contact or interconnect structure, also referred to as an MD local interconnect (MDLI), or local interconnect (LI) in some embodiments, is configured to be electrically connected to the S/D structures of both the p-type FET and the n-type FET of a CFET.

A gate region/structure, e.g., a gate region/structure G, also referred to as a gate G in some embodiments, is a region in the IC layout diagram included in the manufacturing process as part of defining a gate structure. A gate structure is a volume including one or more conductive segments, e.g., a gate electrode, including one or more conductive materials, e.g., polysilicon, copper (Cu), aluminum (Al), tungsten (W), cobalt (Co), ruthenium (Ru), or one or more other metals or other suitable materials, substantially surrounded by one or more insulating materials, the one or more conductive segments thereby being configured to control a voltage provided at an adjacent gate dielectric layer.

A gate dielectric layer, e.g., a gate dielectric layer of a gate structure G, is a volume including one or more insulating materials, e.g., silicon dioxide, silicon nitride (Si₃N₄), and/or one or more other suitable material such as a low-k material having a k value less than 3.8 or a high-k material having a k value greater than 3.8 or 7.0 such as aluminum oxide (Al₂O₃), hafnium oxide (HfO₂), tantalum pentoxide (Ta₂O₅), or titanium oxide (TiO₂), suitable for providing a high electrical resistance between IC structure elements, i.e., a resistance level above a predetermined threshold corresponding to one or more tolerance levels of a resistance-based effect on circuit performance.

In some embodiments, a gate region/structure corresponds to a dummy gate region/structure. In some embodiments, a dummy gate region/structure includes a gate electrode electrically connected, e.g., tied-off, to one or more features, e.g., a power rail or other metal segment or an adjacent instance of a S/D region/structure such that a transistor corresponding to the dummy gate region/structure and overlapping/underlying active region/area is switched off by design. In some embodiments, a dummy gate region/structure that overlaps/overlies an edge of an active region/area is referred to as a continuous poly on oxide definition edge (CPODE) region/structure.

A cut-gate region, e.g., a cut-gate region CPO, also referred to as a cut-poly region in some embodiments, is a region in the IC layout diagram included in the manufacturing process as part of defining a discontinuity in a given gate structure, e.g., a portion etched away after the gate electrode has been formed, thereby resulting in adjacent and aligned gate electrode segments electrically isolated from each other.

A metal line or region, e.g., a frontside metal region/segment M0A or M0B, or a backside metal region/segment BM0, is a region in the IC layout diagram included in the manufacturing process as part of defining a metal line, or segment, including one or more conductive materials, e.g., polysilicon, copper (Cu), aluminum (Al), tungsten (W), cobalt (Co), ruthenium (Ru), or one or more other metals or other suitable materials, in a given frontside or backside metal layer of the manufacturing process.

In some embodiments, a metal region/segment, e.g., metal region/segment M0A or M0B, corresponds to a first, or lowermost, frontside metal layer (also referred to as a metal zero layer or frontside metal zero layer in some embodiments), or a second or higher level frontside metal layer of the manufacturing process. In some embodiments, a second frontside metal layer is referred to as a metal one layer or frontside metal one layer and a second frontside metal region/segment is referred to as a metal one region/segment.

In some embodiments, a backside metal region/segment, e.g., metal region/segment BM0, corresponds to a first, or lowermost, backside metal layer (also referred to as a backside metal zero layer in some embodiments), or a second or higher level backside metal layer of the manufacturing process.

In some embodiments, a metal region/segment corresponds to a component of a power distribution network configured to distribute one or both of a power supply voltage, e.g., a power supply voltage VDD, and/or a reference or ground voltage, e.g., reference voltage VSS. The power distribution network component is electrically connected to one or more features, e.g., additional metal regions/segments and/or via regions/structures, configured to distribute the corresponding power supply or reference voltage and be electrically isolated from IC components outside the distribution network.

A via region/structure, e.g., a via region/structure VD, VDR, or CVDD, also referred to as a via or interconnect in some embodiments, is a region in the IC layout diagram included in the manufacturing process as part of defining a via/interconnect structure including one or more conductive materials configured to provide an electrical connection between a first, e.g., overlying, conductive structure, e.g., a frontside metal segment M0A or M0B or backside metal segment BM0, and a second, e.g., underlying, conductive structure, e.g., a metal segment, a gate electrode of a gate structure G, a contact structure CT, an interconnect structure MDLI, or a S/D structure SD, aligned with the first conductive structure in the Z direction.

In some embodiments, a via region/structure VD and/or backside via region/structure VDR or CVDD corresponds to the underlying conductive structure being a S/D region/structure SD, contact region/structure CT, or interconnect region/structure MDLI.

In some embodiments, an interconnect region/structure MDLI, also referred to as a local interconnect region/structure MDLI or vertical local interconnect region/structure MDLI in some embodiments, corresponds to each of the underlying or overlying conductive structures being one or more instances of a contact region/structure CT, a frontside via region/structure VD, or a backside via region/structure VDR or CVDD.

FIG. 1A is a schematic diagram of a cell MC included in each of IC layouts/devices 100-400, FIG. 1B includes a plan view of IC layout diagram/device 100 and X and Y directions, and FIGS. 1C and 1D include cross-sectional views of IC layout diagram/device 100 along respective lines A-A′ and B-B′ of FIG. 1B, the X direction and a Z direction. FIGS. 2A and 2B include plan views of IC layout diagram/device 200 and the X and Y directions, and FIGS. 2C and 2D include cross-sectional views of IC layout diagram/device 200 along respective lines C-C′ and D-D′ of FIG. 2A and the X and Z directions. Each of FIGS. 3 and 4 includes a plan view of the respective IC layout diagram/device 300 or 400 and the X and Y directions. In some cases, for the purpose of clarity, not all instances of each feature included IC layout diagrams/devices 100-400 are labeled in FIGS. 1A-4.

As depicted in FIGS. 1C, 1D, 2C, and 2D and discussed below, IC layout diagrams/devices 100-400 correspond to instances of a stacked CFET having epitaxial S/D structures and including an upper n-type FET (also referred to as an n-type transistor in some embodiments) and a lower p-type FET (also referred to as a p-type transistor in some embodiments). The upper n-type transistor is positioned at a first elevation further along a positive Z direction than a second elevation along the positive Z direction at which the lower p-type transistor is positioned. In some embodiments, the upper transistor includes a p-type transistor, the lower transistor includes an n-type transistor, and the features discussed below have opposite orientations accordingly.

IC layout diagrams/devices including the configurations discussed below corresponding to other transistor types, e.g., fin field-effect transistors (FinFETs) or planar transistors, are within the scope of the present disclosure.

As depicted in FIGS. 1A-4, each of IC layout diagrams/devices 100-400 includes one or more instances of cell MC, also referred to as a memory cell MC, SRAM cell MC, or six-transistor SRAM (6T SRAM) cell MC in some embodiments, as further discussed below. A given instance of cell MC corresponds to an IC layout diagram configured to be stored in a storage device, e.g., a cell library such as cell library 707 discussed below with respect to IC layout diagram generation system 700, that at least partially defines an IC structure or device within a corresponding area of an IC manufactured based on the cell.

The features within a given cell MC are configured in accordance with the schematic diagram of FIG. 1A. As depicted in FIG. 1A, cell MC corresponds to a six-transistor SRAM device including two series connections of a p-type pull-up transistor PU and an n-type pull-down transistor PD cross-coupled between a power supply voltage node VDD and a reference voltage node VSS. Corresponding instances of an internal node ND are coupled to bit lines BL/BLB through instances of an n-type pass-gate transistor PG, each instance including a gate coupled to a word line WL. In some embodiments, one or both instances of pass-gate transistor PG, also referred to as a pass gate PG in some embodiments, is a p-type transistor.

In operation, cell MC is configured to receive/output data bits from/to bit lines BL/BLB through pass-gate transistors PG responsive to word line signals received on word line WL, and store the data bits as complementary pairs on internal nodes ND. In some embodiments, bit lines BL/BLB are referred to as complementary bit lines BL/BLB, bit line pair BL/BLB, or complementary bit line pair BL/BLB.

As depicted in FIGS. 1B-4, each of IC layout diagrams/devices 100-400 includes two instances of cell MC adjacent to each other along the X direction. In some embodiments, one or more of layout diagrams/devices 100-400 includes a single instance of cell MC. In some embodiments, one or more of layouts/devices 100-400 includes one or more additional instances of cell MC adjacent to one or more of those depicted along the X direction and/or one or more instances of cell MC adjacent to one or more additional instances along the Y direction, e.g., configured as an array of instances of cell MC.

In each of the embodiments depicted in FIGS. 1B-4, a total of four CFETs are configured in substrate SUB as each instance of cell MC. The four CFETs include two CFETs in which an n-type pull-down transistor PD is stacked over a p-type pull-up transistor PU, and two CFETs in which an n-type pass-gate transistor PG is positioned at a same elevation in the Z direction as the n-type pull-down transistors, and stacked over a region of substrate SUB that is free from including a p-type transistor. In some embodiments, an n-type pass-gate transistor PG of a CFET is stacked over a p-type transistor, e.g., an additional instance of a pull-up transistor PU.

In some embodiments, two CFETs include a p-type pass-gate transistor PG positioned at a same elevation in the Z direction as the p-type pull-up transistors PU, and stacked under a region of substrate SUB that is free from including an n-type transistor or under another n-type transistor, e.g., an n-type pass-gate transistor configured in combination with the p-type pass-gate transistor as a transmission gate PG.

In the embodiments depicted in FIGS. 1B-4, each instance of cell MC includes each of the two pull-down/up transistor PD/PU CFETs aligned with one of the pass-gate transistor PG CFETs in the X direction and with the other of the transistor PG CFETs in the Y direction, with the two instances of cell MC being symmetrical about a shared border along the Y direction.

In the embodiments depicted in the cross-sections of FIGS. 1C, 1D, 2C, and 2D, the S/D regions/structures SD of each instance of pass-gate transistor PG and pull-down transistor PD include respective epitaxial regions/layers PG_NEPI and PD_NEPI, and the S/D regions/structures of each instance of pull-up transistor PU include epitaxial regions/layers PU_PEPI. Other configurations of S/D regions/structures SD are within the scope of the present disclosure.

As depicted in FIGS. 1B, 1C and 2A-2C, adjacent instances of pull-down/up transistor PD/PU CFETs in adjacent instances of cell MC in respective IC layout diagrams/devices 100 and 200 are electrically coupled to each other through a shared instance of contact region/structure CT corresponding to power supply voltage VDD and through a shared instance of contact region/structure CT corresponding to reference voltage VSS.

The shared instance of contact region/structure CT corresponding to power supply voltage VDD is electrically connected through via region/structure CVDD to a backside metal region/segment BM0 configured to have power supply voltage VDD, and the shared instance of contact region/structure CT corresponding to reference voltage VSS is electrically connected through two instances of via region/structure VD to corresponding instances of frontside metal region/segment M0B configured to have reference voltage VSS.

As depicted in FIGS. 1B, 1C and 2A-2C, additional instances of contact region/structure CT are electrically connected through additional instances of via region/structure VD to corresponding instances of frontside metal region/segment M0A configured as bit lines BL.

As depicted in FIGS. 1B and 2A, additional instances of contact region/structure CT are electrically connected through additional instances of via region/structure VD to corresponding additional instances of frontside metal region/segment M0B configured to have reference voltage VSS and to corresponding additional instances of frontside metal region/segment M0A configured as bit lines BLB.

Each instance of via VD extends in the Z direction through one or more dielectric layers, e.g., interlevel dielectric layers ILD1 and ILD2 depicted in FIGS. 1C, 1D, 2C, and 2D.

As depicted in FIGS. 1B, 1D, 2A, 2B, and 2D, instances of interconnect region/structure MDLI correspond to internal nodes ND and are configured to electrically connect S/D regions/structures SD of corresponding instances of pull-down transistors PD (shared with corresponding instances of pass-gate transistors PG) and S/D regions/structures SD of corresponding instances of pull-up transistors PU with each other.

Although not separately depicted, each of IC layout diagrams/devices 300 and 400 includes cross-sectional features analogous to those of IC layout diagrams/devices 100 and 200 depicted in FIGS. 1C, 1D, 2C, and 2D and discussed above.

Each of IC layout diagrams/devices 100-400 is thereby configured as depicted in FIGS. 1B-4 to include the S/D regions/structures SD of the instances of pull-down transistor PD configured to have reference voltage VSS to be electrically coupled to the instances of frontside metal region/segment M0B, and the S/D regions/structures SD of the instances of pass-gate transistor PG to be electrically coupled to instances of frontside metal region/segment M0A at alternating positions along the X direction.

Each instance of frontside metal region/segment M0B is configured to have reference voltage VSS, and alternating instances of frontside metal region/segment M0A are configured as instances of complementary bit lines BL and BLB.

The instances of frontside metal region/segment M0B have a width Ws, and the instances of frontside metal region/segment M0A have a width Wb. In various embodiments, the instances of frontside metal region/segment M0B have a same value or multiple values of width Ws and/or the instances of frontside metal region/segment M0A have a same value or multiple values of width Wb.

In the embodiments depicted in FIGS. 1B-4, width Wb has each of one or more values greater than each of one or more values of width Ws. In some embodiments, width Wb has at least one value equal to or less than at least one value of width Ws.

The instances of pull-down transistor PD configured to have reference voltage VSS are electrically coupled to the instances of frontside metal region/segment M0B through corresponding instances of via region/structure VD having a maximum diameter D1, also referred to as a diameter D1 or width D1 in some embodiments. In some embodiments, as width Ws increases relative to diameter D1, a parasitic capacitance level of frontside metal region/segment M0B increases and a parasitic resistance level of frontside metal region/segment M0B decreases.

In some embodiments, a ratio of width Ws to diameter D1 ranges from 0.7 to less than or equal to 1.2. In some embodiments, a ratio of width Ws to diameter D1 ranges from 1.2 to less than or equal to 3.0.

In some embodiments, the instances of frontside metal region/segment M0A correspond to a first mask of two or more masks used in a manufacturing process, e.g., as discussed below with respect to one or more masks 845 and FIG. 8, and the instances of frontside metal region/segment M0B correspond to a second mask of the two or more masks. In some embodiments, the instances of frontside metal region/segment M0A and frontside metal region/segment M0B correspond to a same mask.

In the embodiment depicted in FIGS. 1A-1D, IC layout diagram/device 100 includes the instances of frontside metal region/segment M0B spaced equidistantly between the instances of frontside metal region/segment M0A, the corresponding instances accordingly being separated by an approximately equal distance S1 in the X direction. Distances between features, e.g., distance S1, are considered to be approximately equal by having values that differ by less than a predetermined amount, e.g., a manufacturing tolerance.

In the embodiment depicted in FIGS. 2A-2D, IC layout diagram/device 200 includes the instances of frontside metal region/segment M0B spaced apart from corresponding instances of frontside metal region/segment M0A in the negative X direction by a distance S2 and from corresponding instances of frontside metal region/segment M0A in the positive X direction by a distance S3 greater than distance S2. In some embodiments, distance S2 corresponds to a minimum spacing rule of a manufacturing process used to manufacture IC device 200 based on IC layout diagram 200.

As depicted in FIG. 2B, in some embodiments, IC layout diagram/device 200 includes one or more instances of a cell LC including CFETs (not shown) configured as one or more logic circuits, e.g., a control, decode, or input/output (I/O) circuit of a memory circuit. The one or more instances of cell LC include one or more metal regions/segments (not labeled) configured as signal lines and are aligned with corresponding one or more instances of frontside metal region/segment M0B in the Y direction, e.g., based on each corresponding signal line and frontside metal region M0B being aligned to a same instance of a metal line track TR.

As depicted in FIGS. 1B-2D, each of IC layout diagram/device 100 and 200 includes a total of two instances of each of frontside metal region/segment M0B and frontside metal region/segment M0A extending across each instance of cell MC in the Y direction.

As depicted in FIG. 3, IC layout diagram/device 300 is configured to include instances of each of frontside metal region/segment M0B and frontside metal region/segment M0A having the relative spacing of IC layout diagram/device 100 as discussed above. Compared to IC layout diagram/device 100, the instances of frontside metal region/segment M0B and frontside metal region/segment M0A are oriented with respect to cells MC such that alternating instances of frontside metal region/segment M0B are shared between adjacent instances of cell MC.

As depicted in FIG. 4, IC layout diagram/device 400 is configured to include instances of each of frontside metal region/segment M0B and frontside metal region/segment M0A having the relative spacing of IC layout diagram/device 200 as discussed above. Compared to IC layout diagram/device 200, the instances of frontside metal region/segment M0B and frontside metal region/segment M0A are oriented with respect to cells MC such that alternating instances of frontside metal region/segment M0B are shared between adjacent instances of cell MC.

Each of IC layout diagrams/devices 100-400 is thereby configured as discussed above to include instances of frontside metal region/segment M0B electrically connected to S/D regions/structures SD of CFET pull-down transistors PD configured to have reference voltage VSS and extending in the Y direction between instances of frontside metal region/segment M0A configured as bit lines BL and BLB and electrically connected to corresponding S/D regions/structures SD of CFET pass-gate transistors PG.

By including a reference voltage line VSS between each instance of bit line BL and BLB, each IC layout diagram/device 100-400 is capable of having reduced capacitive coupling between the bit lines of each SRAM cell MC compared to approaches that do not include a reference voltage line between bit lines of an SRAM device, thereby enabling relatively higher operating speeds.

In the embodiments depicted in FIGS. 2A-2D and 4, IC layout diagrams/devices 200 and 400 including instances of voltage line VSS having asymmetrical spacing between adjacent instances of bit line BL and BLB is thereby capable of further reduced capacitive coupling, e.g., by 10-15%, compared to IC layout diagrams/devices 100 and 300.

FIG. 5 is a flowchart of method 500 of manufacturing an IC device, in accordance with some embodiments. Method 500 is operable to form some or all of one or more of IC devices 100-400 discussed above with respect to FIGS. 1A-4.

In some embodiments, performing some or all of the operations of method 500 is part of building a plurality of IC devices, e.g., transistors, logic gates, memory cells, interconnect structures, and/or other suitable devices, by performing a plurality of manufacturing operations, e.g., one or more of a lithography, diffusion, deposition, etching, planarizing, or other operation suitable for building the plurality of IC devices in a semiconductor substrate.

In some embodiments, the operations of method 500 are performed in the order depicted in FIG. 5. In some embodiments, the operations of method 500 are performed in an order other than the order depicted in FIG. 5. In some embodiments, one or more additional operations are performed before, during, and/or after the operations of method 500. In some embodiments, performing some or all of the operations of method 500 includes performing one or more operations as discussed below with respect to IC manufacturing system 800 and FIG. 8.

At operation 502, first through fourth CFETs are constructed by configuring the first through fourth CFETs as a SRAM device including first and second pass-gate transistors and first and second pull-down transistors. Constructing the CFETs includes constructing the first CFET by forming a first pull-down transistor at a first elevation along a first direction and a first pull-up transistor at a second elevation along the first direction, constructing the second CFET by forming a first pass-gate transistor at the first elevation and aligned with the first pull-down transistor in a second direction perpendicular to the first direction, constructing the third CFET by forming a second pass-gate transistor at the first elevation and aligned with the first pull-down transistor in a third direction perpendicular to the first and second directions, and constructing the fourth CFET by forming a second pull-down transistor at the first elevation, aligned with the first pass-gate transistor in the third direction, and aligned with the second pass-gate transistor in the second direction, and a second pull-up transistor at the second elevation.

In various embodiments, constructing the first through fourth CFETs includes the first elevation being further along a positive Z direction than the second elevation or the second elevation being further along the positive Z direction than the first elevation, e.g., as discussed above with respect to FIGS. 1A-4.

In some embodiments, constructing the first through fourth CFETs includes constructing the instances of CFETs corresponding to one or more instances of memory cell MC as discussed above with respect to IC layout diagrams/devices 100-400 and FIGS. 1A-4.

Constructing the first through fourth CFETs includes performing a plurality of manufacturing processes including one or more of a lithography, diffusion, implantation, deposition, plasma treatment, etching, planarizing, spin coating, soft-baking, exposure, post-baking, developing, rinsing, drying, or other suitable operation.

At operation 504, first and second bit lines are formed electrically connected to S/D structures of the first and second pass-gate transistors and a reference voltage line electrically connected to a S/D structure of a pull-down transistor and extending between the first and second bit lines. Forming the first and second bit lines and the reference voltage line includes forming the first and second bit lines and the reference voltage line at a third elevation along the first direction different from the first and second elevations.

In various embodiments, forming the first and second bit lines and the reference voltage line includes forming frontside metal segments or backside metal segments, e.g., as discussed above with respect to FIGS. 1A-4.

In some embodiments, forming the first and second bit lines and the reference voltage line includes forming instances of bit lines BL and BLB, reference voltage line VSS, and via structures VD as discussed above with respect to FIGS. 1A-4.

Forming the first and second bit lines and the reference voltage line includes performing a plurality of manufacturing operations including depositing and patterning one or more photoresist layers, performing one or more etching processes, and performing one or more deposition processes whereby one or more conductive materials are configured to form a plurality of continuous, low resistance structures.

At operation 506, additional electrical connections to the SRAM device are formed. In some embodiments, forming the additional electrical connections includes forming backside conductive lines, e.g., one or more instances of power supply voltage line VDD as discussed above with respect to FIGS. 1A-4.

In some embodiments, forming the additional electrical connections includes forming frontside conductive lines prior to performing operation 504, e.g., forming one or more instances of a power supply voltage line as discussed above with respect to FIGS. 1A-4.

In some embodiments, forming the backside via includes forming a plurality of backside vias, e.g., including the backside via on the MD segment, and forming the backside conductive line includes forming a plurality of backside conductive lines on the plurality of backside vias.

Forming the additional electrical connections includes performing a plurality of manufacturing operations including depositing and patterning one or more photoresist layers, performing one or more etching processes, and performing one or more deposition processes whereby one or more conductive materials are configured to form a plurality of continuous, low resistance structures.

By performing some or all of the operations of method 500, an IC device is manufactured in which an SRAM device includes a reference voltage line positioned between bit lines of a bit line pair, thereby enabling the realization of the benefits discussed above with respect to IC devices 100-400.

FIG. 6 is a flowchart of method 600 of generating an IC layout diagram, e.g., a memory cell MC and/or one or more of IC layout diagrams 100-400 discussed above with respect to FIGS. 1A-4, in accordance with some embodiments.

In some embodiments, generating the IC layout diagram includes generating the IC layout diagram corresponding to an IC device, e.g., IC device 100-400 discussed above with respect to FIGS. 1A-4, manufactured based on the generated IC layout diagram.

In some embodiments, some or all of method 600 is executed by a processor of a computer, e.g., a processor 702 of an IC layout diagram generation system 700, discussed below with respect to FIG. 7.

Some or all of the operations of method 600 are capable of being performed as part of a design procedure performed in a design house, e.g., a design house 820 discussed below with respect to FIG. 8.

In some embodiments, the operations of method 600 are performed in the order depicted in FIG. 6. In some embodiments, the operations of method 600 are performed simultaneously and/or in an order other than the order depicted in FIG. 6. In some embodiments, one or more operations are performed before, between, during, and/or after performing one or more operations of method 600.

At operation 602, in some embodiments, a bit line pair is arranged across a SRAM cell including first through fourth CFETs, the bit lines being electrically connected to S/D regions of pass-gate transistors of the SRAM cell. In some embodiments, arranging the bit line pair across the SRAM cell includes arranging one or more instances of bit lines BL and BLB across one or more corresponding instances of memory cell MC as discussed above with respect to FIGS. 1A-4.

At operation 604, in some embodiments, a reference voltage line is arranged between the bit lines and electrically connected to a pull-down transistor of the SRAM cell. In some embodiments, arranging the reference voltage line includes arranging one or more instances of reference voltage line VSS between one or more corresponding instances of bit lines BL and BLB as discussed above with respect to FIGS. 1A-4.

At operation 606, in some embodiments, the cell is abutted with a second cell in the IC layout diagram. In some embodiments, abutting the cell with the second cell includes abutting instances of cell MC with each other and/or with additional instances of cell MC in IC layout diagram 100-400 as discussed above with respect to FIGS. 1A-4.

At operation 608, in some embodiments additional lines electrically connected to the SRAM cell are arranged. In some embodiments, arranging the additional lines includes arranging one or more instances of power supply voltage line VDD as discussed above with respect to FIGS. 1A-4.

At operation 610, in some embodiments, the IC layout diagram including the SRAM cell(s) is stored in a storage device. In some embodiments, storing the IC layout diagram in the storage device includes storing one or more instances of cell MC or IC layout diagram 100-400, discussed above with respect to FIGS. 1A-4, in the storage device.

In some embodiments, storing the IC layout diagram in the storage device includes storing the IC layout diagram in a non-volatile, computer-readable memory or a database, and/or includes storing the IC layout diagram over a network. In some embodiments, storing the IC layout diagram in the storage device includes storing the IC layout diagram in cell library 707 or layout diagrams 709 and/or over network 714 of IC layout diagram generation system 700, discussed below with respect to FIG. 7.

At operation 612, in some embodiments, one or more manufacturing operations, one or more lithographic exposures, are performed based on the IC layout diagram. Non-limiting examples of performing one or more manufacturing operations, e.g., one or more lithographic exposures, based on the IC layout diagram are discussed above with respect to FIG. 5 and below with respect to FIG. 8.

By executing some or all of the operations of method 600, an IC layout diagram is generated corresponding to an IC device in which in which an SRAM device includes a reference voltage line positioned between bit lines of a bit line pair, thereby enabling the realization of the benefits discussed above with respect to IC devices 100-400.

FIG. 7 is a block diagram of IC layout diagram generation system 700, in accordance with some embodiments. Methods described herein of designing IC layout diagrams in accordance with one or more embodiments are implementable, for example, using IC layout diagram generation system 700, in accordance with some embodiments.

In some embodiments, IC layout diagram generation system 700 is a general purpose computing device including a hardware processor 702 and a non-transitory, computer-readable storage medium 704. Storage medium 704, amongst other things, is encoded with, i.e., stores, computer program code 706, i.e., a set of executable instructions. Execution of instructions 706 by hardware processor 702 represents (at least in part) an electronic design automation (EDA) tool which implements a portion or all of a method, e.g., method 600 of generating an IC layout diagram described above with respect to FIG. 6 (hereinafter, the noted processes and/or methods).

Processor 702 is electrically coupled to computer-readable storage medium 704 via a bus 708. Processor 702 is also electrically coupled to an I/O interface 710 by bus 708. A network interface 712 is also electrically connected to processor 702 via bus 708. Network interface 712 is connected to a network 714, so that processor 702 and computer-readable storage medium 704 are capable of connecting to external elements via network 714. Processor 702 is configured to execute computer program code 706 encoded in computer-readable storage medium 704 in order to cause IC layout diagram generation system 700 to be usable for performing a portion or all of the noted processes and/or methods. In one or more embodiments, processor 702 is a central processing unit (CPU), a multi-processor, a distributed processing system, an application specific integrated circuit (ASIC), and/or a suitable processing unit.

In one or more embodiments, computer-readable storage medium 704 is an electronic, magnetic, optical, electromagnetic, infrared, and/or a semiconductor system (or apparatus or device). For example, computer-readable storage medium 704 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 704 includes a compact disk-read only memory (CD-ROM), a compact disk-read/write (CD-R/W), and/or a digital video disc (DVD).

In one or more embodiments, computer-readable storage medium 704 stores computer program code 706 configured to cause IC layout diagram generation system 700 (where such execution represents (at least in part) the EDA tool) to be usable for performing a portion or all of the noted processes and/or methods. In one or more embodiments, computer-readable storage medium 704 also stores information which facilitates performing a portion or all of the noted processes and/or methods.

In one or more embodiments, computer-readable storage medium 704 stores cell library 707 of cells including such cells as disclosed herein, e.g., memory cell MC discussed above with respect to FIGS. 1A-4.

In one or more embodiments, computer-readable storage medium 704 stores layout diagrams 709 including such IC layout diagrams as disclosed herein, e.g., IC layout diagrams 100-400 discussed above with respect to FIGS. 1A-4.

IC layout diagram generation system 700 includes I/O interface 710. I/O interface 710 is coupled to external circuitry. In one or more embodiments, I/O interface 710 includes a keyboard, keypad, mouse, trackball, trackpad, touchscreen, and/or cursor direction keys for communicating information and commands to processor 702.

IC layout diagram generation system 700 also includes network interface 712 coupled to processor 702. Network interface 712 allows system 700 to communicate with network 714, to which one or more other computer systems are connected. Network interface 712 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more IC layout diagram generation systems 700.

IC layout diagram generation system 700 is configured to receive information through I/O interface 710. The information received through I/O interface 710 includes one or more of instructions, data, design rules, libraries of standard cells, and/or other parameters for processing by processor 702. The information is transferred to processor 702 via bus 708. IC layout diagram generation system 700 is configured to receive information related to a UI through I/O interface 710. The information is stored in computer-readable medium 704 as user interface (UI) 742.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by IC layout diagram generation system 700. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 8 is a block diagram of IC manufacturing system 800, and an IC manufacturing flow associated therewith, in accordance with some embodiments. In some embodiments, based on an IC layout diagram, at least one of (A) one or more semiconductor masks or (B) at least one component in a layer of a semiconductor integrated circuit is fabricated using manufacturing system 800.

In FIG. 8, IC manufacturing system 800 includes entities, such as a design house 820, a mask house 830, and an IC manufacturer/fabricator (“fab”) 850, that interact with one another in the design, development, and manufacturing cycles and/or services related to manufacturing an IC device 860. The entities in system 800 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 820, mask house 830, and IC fab 850 is owned by a single larger company. In some embodiments, two or more of design house 820, mask house 830, and IC fab 850 coexist in a common facility and use common resources.

Design house (or design team) 820 generates an IC design layout diagram 822. IC design layout diagram 822 includes various geometrical patterns, e.g., one or more of IC layout diagrams 100-400 discussed above with respect to FIGS. 1A-4. The geometrical patterns correspond to patterns of metal, oxide, or semiconductor layers that make up the various components of IC device 860 to be fabricated. The various layers combine to form various IC features. For example, a portion of IC design layout diagram 822 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 820 implements a proper design procedure to form IC design layout diagram 822. The design procedure includes one or more of logic design, physical design or place and route. IC design layout diagram 822 is presented in one or more data files having information of the geometrical patterns. For example, IC design layout diagram 822 can be expressed in a GDSII file format or DFII file format.

Mask house 830 includes data preparation 832 and mask fabrication 844. Mask house 830 uses IC design layout diagram 822 to manufacture one or more masks 845 to be used for fabricating the various layers of IC device 860 according to IC design layout diagram 822. Mask house 830 performs mask data preparation 832, where IC design layout diagram 822 is translated into a representative data file (RDF). Mask data preparation 832 provides the RDF to mask fabrication 844. Mask fabrication 844 includes a mask writer. A mask writer converts the RDF to an image on a substrate, such as a mask (reticle) 845 or a semiconductor wafer 853. The design layout diagram 822 is manipulated by mask data preparation 832 to comply with particular characteristics of the mask writer and/or requirements of IC fab 850. In FIG. 8, mask data preparation 832 and mask fabrication 844 are illustrated as separate elements. In some embodiments, mask data preparation 832 and mask fabrication 844 can be collectively referred to as mask data preparation.

In some embodiments, mask data preparation 832 includes optical proximity correction (OPC) which uses lithography enhancement techniques to compensate for image errors, such as those that can arise from diffraction, interference, other process effects and the like. OPC adjusts IC design layout diagram 822. In some embodiments, mask data preparation 832 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 832 includes a mask rule checker (MRC) that checks the IC design layout diagram 822 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 822 to compensate for limitations during mask fabrication 844, which may undo part of the modifications performed by OPC in order to meet mask creation rules.

In some embodiments, mask data preparation 832 includes lithography process checking (LPC) that simulates processing that will be implemented by IC fab 850 to fabricate IC device 860. LPC simulates this processing based on IC design layout diagram 822 to create a simulated manufactured device, such as IC device 860. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 822.

It should be understood that the above description of mask data preparation 832 has been simplified for the purposes of clarity. In some embodiments, data preparation 832 includes additional features such as a logic operation (LOP) to modify the IC design layout diagram 822 according to manufacturing rules. Additionally, the processes applied to IC design layout diagram 822 during data preparation 832 may be executed in a variety of different orders.

After mask data preparation 832 and during mask fabrication 844, a mask 845 or a group of masks 845 are fabricated based on the modified IC design layout diagram 822. In some embodiments, mask fabrication 844 includes performing one or more lithographic exposures based on IC design layout diagram 822. In some embodiments, an electron-beam (e-beam) or a mechanism of multiple e-beams is used to form a pattern on a mask (photomask or reticle) 845 based on the modified IC design layout diagram 822. Mask 845 can be formed in various technologies. In some embodiments, mask 845 is formed using binary technology. In some embodiments, a mask pattern includes opaque regions and transparent regions. A radiation beam, such as an ultraviolet (UV) or EUV beam, used to expose the image sensitive material layer (e.g., photoresist) which has been coated on a wafer, is blocked by the opaque region and transmits through the transparent regions. In one example, a binary mask version of mask 845 includes a transparent substrate (e.g., fused quartz) and an opaque material (e.g., chromium) coated in the opaque regions of the binary mask. In another example, mask 845 is formed using a phase shift technology. In a phase shift mask (PSM) version of mask 845, various features in the pattern formed on the phase shift mask are configured to have proper phase difference to enhance the resolution and imaging quality. In various examples, the phase shift mask can be attenuated PSM or alternating PSM. The mask(s) generated by mask fabrication 844 is used in a variety of processes. For example, such a mask(s) is used in an ion implantation process to form various doped regions in semiconductor wafer 853, in an etching process to form various etching regions in semiconductor wafer 853, and/or in other suitable processes.

IC fab 850 is an IC fabrication business that includes one or more manufacturing facilities for the fabrication of a variety of different IC products. In some embodiments, IC Fab 850 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 850 includes wafer fabrication tools 852 configured to execute various manufacturing operations on semiconductor wafer 853 such that IC device 860 is fabricated in accordance with the mask(s), e.g., mask 845. In various embodiments, fabrication tools 852 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 850 uses mask(s) 845 fabricated by mask house 830 to fabricate IC device 860. Thus, IC fab 850 at least indirectly uses IC design layout diagram 822 to fabricate IC device 860. In some embodiments, semiconductor wafer 853 is fabricated by IC fab 850 using mask(s) 845 to form IC device 860. In some embodiments, the IC fabrication includes performing one or more lithographic exposures based at least indirectly on IC design layout diagram 822. Semiconductor wafer 853 includes a silicon substrate or other proper substrate having material layers formed thereon. Semiconductor wafer 853 further includes one or more of various doped regions, dielectric features, multilevel interconnects, and the like (formed at subsequent manufacturing steps).

In some embodiments, an IC device includes first through fourth CFETs configured in a substrate as a first SRAM device, wherein the first CFET includes a first pull-down transistor positioned at a first elevation along a first direction and a first pull-up transistor positioned at a second elevation along the first direction, the second CFET includes a first pass-gate transistor positioned at the first elevation and aligned with the first pull-down transistor in a second direction perpendicular to the first direction, the third CFET includes a second pass-gate transistor positioned at the first elevation and aligned with the first pull-down transistor in a third direction perpendicular to the first and second directions, and the fourth CFET includes a second pull-down transistor positioned at the first elevation, aligned with the first pass-gate transistor in the third direction, and aligned with the second pass-gate transistor in the second direction, and a second pull-up transistor positioned at the second elevation, a first bit line extending in the third direction at a third elevation along the first direction and electrically connected to a S/D structure of the first pass-gate transistor, a second bit line extending in the third direction at the third elevation and electrically connected to a S/D structure of the second pass-gate transistor, and a first reference voltage line extending between the first and second bit lines at the third elevation and electrically connected to a S/D structure of the first pull-down transistor. In some embodiments, the first and second bit lines have widths greater than a width of the first reference voltage line. In some embodiments, a distance between the first reference voltage line and the first bit line is approximately equal to a distance between the first reference voltage line and the second bit line. In some embodiments, a distance between the first reference voltage line and the first bit line is greater than a distance between the first reference voltage line and the second bit line. In some embodiments, the IC device includes a plurality of additional CFETs configured in the substrate as a logic circuit, wherein a signal line of the logic circuit is aligned with the first reference voltage line in the third direction. In some embodiments, the IC device includes a second reference voltage line positioned at the third elevation and electrically connected to a S/D structure of the second pull-down transistor, wherein the second bit line extends between the first and second reference voltage lines. In some embodiments, the IC device includes a third reference voltage line positioned at the third elevation and electrically connected to the S/D structure of the first pull-down transistor, wherein the first bit line extends between the first and third reference voltage lines. In some embodiments, the IC device includes fifth through eighth CFETs configured in the substrate as a second SRAM device adjacent to the first SRAM device in the second direction, wherein the fifth CFET includes a third pull-down transistor positioned at the first elevation and a third pull-up transistor positioned at the second elevation, the sixth CFET includes a third pass-gate transistor positioned at the first elevation and aligned with the third pull-down transistor in the second direction, the seventh CFET includes a fourth pass-gate transistor positioned at the first elevation and aligned with the third pull-down transistor in the third direction, and the eighth CFET includes a fourth pull-down transistor positioned at the first elevation, aligned with the third pass-gate transistor in the third direction, and aligned with the fourth pass-gate transistor in the second direction, and a fourth pull-up transistor positioned at the second elevation, a third bit line extending in the third direction at the third elevation and electrically connected to a S/D structure of the third pass-gate transistor, a fourth bit line extending in the third direction at the third elevation and electrically connected to a S/D structure of the fourth pass-gate transistor, and a second reference voltage line extending between the third and fourth bit lines at the third elevation and electrically connected to a S/D structure of the third pull-down transistor. In some embodiments, each of the first through third elevations corresponds to a position on a front side of the substrate. In some embodiments, the IC device includes a power supply voltage line extending in the third direction, electrically connected to a S/D structure of each of the first and second pull-up transistors, and positioned at a fourth elevation along the third direction corresponding to a position on a back side of the substrate.

In some embodiments, a method of manufacturing an IC device includes constructing, on a front side of a substrate, first through fourth CFETs configured as a SRAM device, constructing the first through fourth CFETs including constructing the first CFET by forming a first pull-down transistor at a first elevation along a first direction and a first pull-up transistor at a second elevation along the first direction, constructing the second CFET by forming a first pass-gate transistor at the first elevation and aligned with the first pull-down transistor in a second direction perpendicular to the first direction, constructing the third CFET by forming a second pass-gate transistor at the first elevation and aligned with the first pull-down transistor in a third direction perpendicular to the first and second directions, and constructing the fourth CFET by forming a second pull-down transistor at the first elevation, aligned with the first pass-gate transistor in the third direction, and aligned with the second pass-gate transistor in the second direction, and a second pull-up transistor at the second elevation, forming a first bit line extending in the third direction at a third elevation along the first direction and electrically connected to a S/D structure of the first pass-gate transistor, forming a second bit line extending in the third direction at the third elevation and electrically connected to a S/D structure of the second pass-gate transistor, and forming a first reference voltage line extending between the first and second bit lines at the third elevation and electrically connected to a S/D structure of the first pull-down transistor. In some embodiments, each of forming the first bit line and forming the second bit line includes using a first mask, and forming the first reference voltage line includes using a second mask. In some embodiments, forming the first reference voltage line includes forming the first reference voltage line having a first width, and each of forming the first bit line and forming the second bit line includes forming the corresponding first or second bit line having a second width greater than the first width. In some embodiments, forming the first reference voltage line includes forming the first reference voltage line equidistant from each of the first bit line and the second bit line. In some embodiments, forming the first reference voltage line includes forming a second reference voltage line electrically connected to a S/D structure of the second pull-down transistor, and the second bit line extends between the first and second reference voltage lines. In some embodiments, each of forming the first bit line, forming the second bit line, and forming the reference voltage line includes forming the corresponding first or second bit line or first reference voltage line on the front side of the substrate, and the method includes forming a power supply voltage line on a back side of the substrate and electrically connected to a S/D structure of each of the first and second pull-up transistors.

In some embodiments, a method of generating an IC layout diagram includes arranging a bit line pair across a SRAM cell including first through fourth CFETs, wherein the first CFET includes a first pull-down transistor stacked with a first pull-up transistor, the second CFET includes a first pass-gate transistor aligned with the first pull-down transistor in a first direction, the third CFET includes a second pass-gate transistor aligned with the first pull-down transistor in a second direction perpendicular to the first direction, the fourth CFET includes a second pull-down transistor stacked with a second pull-up transistor, aligned with the first pass-gate transistor in the second direction, and aligned with the second pass-gate transistor in the first direction, and the bit lines of the bit line pair are electrically connected to S/D regions of the first and second pass-gate transistors, arranging a reference voltage line between the bit lines of the bit line pair and electrically connected to a S/D region of the first pull-down transistor, and storing the IC layout diagram comprising the SRAM cell comprising the bit line pair and the reference voltage line in a storage device. In some embodiments, wherein arranging the bit line pair includes arranging the bit line pair corresponding to a first mask, and arranging the reference voltage line includes arranging the reference voltage line corresponding to a second mask. In some embodiments, arranging the reference voltage line includes arranging the reference voltage line having a first width, and arranging the bit line pair includes arranging the bit lines of the bit line pair having one or more second widths greater than the first width. In some embodiments, arranging the reference voltage line includes aligning the reference voltage line with a logic circuit signal line track.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device comprising:
first through fourth complementary field-effect transistors (CFETs) configured in a substrate as a first static random-access memory (SRAM) device, wherein
the first CFET comprises a first pull-down transistor positioned at a first elevation along a first direction and a first pull-up transistor positioned at a second elevation along the first direction,
the second CFET comprises a first pass-gate transistor positioned at the first elevation and aligned with the first pull-down transistor in a second direction perpendicular to the first direction,
the third CFET comprises a second pass-gate transistor positioned at the first elevation and aligned with the first pull-down transistor in a third direction perpendicular to the first and second directions, and
the fourth CFET comprises a second pull-down transistor positioned at the first elevation, aligned with the first pass-gate transistor in the third direction, and aligned with the second pass-gate transistor in the second direction, and a second pull-up transistor positioned at the second elevation;
a first bit line extending in the third direction at a third elevation along the first direction and electrically connected to a source/drain (S/D) structure of the first pass-gate transistor;
a second bit line extending in the third direction at the third elevation and electrically connected to a S/D structure of the second pass-gate transistor; and
a first reference voltage line extending between the first and second bit lines at the third elevation and electrically connected to a S/D structure of the first pull-down transistor.

2. The IC device of claim 1, wherein
the first and second bit lines have widths greater than a width of the first reference voltage line.

3. The IC device of claim 1, wherein
a distance between the first reference voltage line and the first bit line is approximately equal to a distance between the first reference voltage line and the second bit line.

4. The IC device of claim 1, wherein
a distance between the first reference voltage line and the first bit line is greater than a distance between the first reference voltage line and the second bit line.

5. The IC device of claim 4, further comprising:
a plurality of additional CFETs configured in the substrate as a logic circuit, wherein a signal line of the logic circuit is aligned with the first reference voltage line in the third direction.

6. The IC device of claim 1, further comprising:
a second reference voltage line positioned at the third elevation and electrically connected to a S/D structure of the second pull-down transistor,
wherein the second bit line extends between the first and second reference voltage lines.

7. The IC device of claim 6, further comprising:
a third reference voltage line positioned at the third elevation and electrically connected to the S/D structure of the first pull-down transistor,
wherein the first bit line extends between the first and third reference voltage lines.

8. The IC device of claim 6, further comprising:
fifth through eighth CFETs configured in the substrate as a second SRAM device adjacent to the first SRAM device in the second direction, wherein
the fifth CFET comprises a third pull-down transistor positioned at the first elevation and a third pull-up transistor positioned at the second elevation,
the sixth CFET comprises a third pass-gate transistor positioned at the first elevation and aligned with the third pull-down transistor in the second direction,
the seventh CFET comprises a fourth pass-gate transistor positioned at the first elevation and aligned with the third pull-down transistor in the third direction, and
the eighth CFET comprises a fourth pull-down transistor positioned at the first elevation, aligned with the third pass-gate transistor in the third direction, and aligned with the fourth pass-gate transistor in the second direction, and a fourth pull-up transistor positioned at the second elevation;
a third bit line extending in the third direction at the third elevation and electrically connected to a S/D structure of the third pass-gate transistor;
a fourth bit line extending in the third direction at the third elevation and electrically connected to a S/D structure of the fourth pass-gate transistor; and
a second reference voltage line extending between the third and fourth bit lines at the third elevation and electrically connected to a S/D structure of the third pull-down transistor.

9. The IC device of claim 1, wherein
each of the first through third elevations corresponds to a position on a front side of the substrate.

10. The IC device of claim 9, further comprising:
a power supply voltage line extending in the third direction, electrically connected to a S/D structure of each of the first and second pull-up transistors, and positioned at a fourth elevation along the third direction corresponding to a position on a back side of the substrate.

11. A method of manufacturing an integrated circuit (IC) device, the method comprising:
constructing, on a front side of a substrate, first through fourth complementary field-effect transistors (CFETs) configured as a static random-access memory (SRAM) device, the constructing the first through fourth CFETs comprising:
constructing the first CFET by forming a first pull-down transistor at a first elevation along a first direction and a first pull-up transistor at a second elevation along the first direction;
constructing the second CFET by forming a first pass-gate transistor at the first elevation and aligned with the first pull-down transistor in a second direction perpendicular to the first direction;
constructing the third CFET by forming a second pass-gate transistor at the first elevation and aligned with the first pull-down transistor in a third direction perpendicular to the first and second directions; and
constructing the fourth CFET by forming a second pull-down transistor at the first elevation, aligned with the first pass-gate transistor in the third direction, and aligned with the second pass-gate transistor in the second direction, and a second pull-up transistor at the second elevation;
forming a first bit line extending in the third direction at a third elevation along the first direction and electrically connected to a source/drain (S/D) structure of the first pass-gate transistor;
forming a second bit line extending in the third direction at the third elevation and electrically connected to a S/D structure of the second pass-gate transistor; and
forming a first reference voltage line extending between the first and second bit lines at the third elevation and electrically connected to a S/D structure of the first pull-down transistor.

12. The method of claim 11, wherein
each of the forming the first bit line and the forming the second bit line comprises using a first mask, and
the forming the first reference voltage line comprises using a second mask.

13. The method of claim 11, wherein
the forming the first reference voltage line comprises forming the first reference voltage line having a first width, and
each of the forming the first bit line and the forming the second bit line comprises forming the corresponding first or second bit line having a second width greater than the first width.

14. The method of claim 11, wherein
the forming the first reference voltage line comprises forming the first reference voltage line equidistant from each of the first bit line and the second bit line.

15. The method of claim 11, wherein
the forming the first reference voltage line comprises forming a second reference voltage line electrically connected to a S/D structure of the second pull-down transistor, and
the second bit line extends between the first and second reference voltage lines.

16. The method of claim 11, wherein
each of the forming the first bit line, the forming the second bit line, and the forming the reference voltage line comprises forming the corresponding first or second bit line or first reference voltage line on the front side of the substrate, and
the method further comprises forming a power supply voltage line on a back side of the substrate and electrically connected to a S/D structure of each of the first and second pull-up transistors.

17. A method of generating an integrated circuit (IC) layout diagram, the method comprising:
arranging a bit line pair across a static random-access memory (SRAM) cell comprising first through fourth complementary field-effect transistors (CFETs), wherein
the first CFET comprises a first pull-down transistor stacked with a first pull-up transistor,
the second CFET comprises a first pass-gate transistor aligned with the first pull-down transistor in a first direction,
the third CFET comprises a second pass-gate transistor aligned with the first pull-down transistor in a second direction perpendicular to the first direction,
the fourth CFET comprises a second pull-down transistor stacked with a second pull-up transistor, aligned with the first pass-gate transistor in the second direction, and aligned with the second pass-gate transistor in the first direction, and
the bit lines of the bit line pair are electrically connected to source/drain (S/D) regions of the first and second pass-gate transistors;
arranging a reference voltage line between the bit lines of the bit line pair and electrically connected to a S/D region of the first pull-down transistor; and
storing the IC layout diagram comprising the SRAM cell comprising the bit line pair and the reference voltage line in a storage device.

18. The method of claim 17, wherein
the arranging the bit line pair comprises arranging the bit line pair corresponding to a first mask, and
the arranging the reference voltage line comprises arranging the reference voltage line corresponding to a second mask.

19. The method of claim 17, wherein
the arranging the reference voltage line comprises arranging the reference voltage line having a first width, and
the arranging the bit line pair comprises arranging the bit lines of the bit line pair having one or more second widths greater than the first width.

20. The method of claim 17, wherein
the arranging the reference voltage line comprises aligning the reference voltage line with a logic circuit signal line track.
